(19) United States
(12) Patent Application Publication
(10) Pub. No.: US 2009/0090904 A1
(43) Pub. Date: Apr. 9, 2009

(54) Organic semiconductor device

(76) Inventors: Sung-hun LEE, Yongin-si (KR); Sang-yeol KIM, Yongin-si (KR); Mu-gyeom KIM, Yongin-si (KR); Jung-bae SONG, Yongin-si (KR)

Correspondence Address: ROBERT E. BUSHNELL & LAW FIRM, 2029 K STREET NW, SUITE 600, WASHINGTON, DC, 20006-1004, US

(21) Appl. No.: 12/078,647

(22) Filed: Apr. 2, 2008

(30) Foreign Application Priority Data
Oct. 8, 2007 (KR) 10-2007-0100887

(51) Int. Cl. H01L 29/808

(52) U.S. Cl. 257/40; 257/E27.001

(57) ABSTRACT

Provided is an organic tunneling p-n junction diode. The organic tunneling p-n junction diode includes an n-doped organic semiconductor layer and a p-doped organic semiconductor layer which are doped with extrinsic impurities. When either a reverse-bias voltage or a forward-bias voltage is applied, the organic tunneling p-n junction diode is turned off within a predetermined voltage range and has exponential voltage-current characteristics outside the predetermined voltage range.

### CLAIM OF PRIORITY

This application makes reference to, incorporates the same herein, and claims all benefits accruing under 35 U.S.C.§119 from an application earlier filed in the Korean Intellectual Property Office on Oct. 8, 2007 and there duly assigned Serial No. 10-2007-0100887.

### BACKGROUND OF THE INVENTION

1. Field of the Invention

The present invention relates to an organic semiconductor device, and more particularly, to an organic tunneling p-n junction diode.

2. Description of the Related Art

Organic semiconductor devices can be more easily manufactured at lower costs than inorganic semiconductor devices. Also, the organic semiconductor devices are structurally flexible and can be made thin. The organic semiconductor devices having these many advantages over the inorganic semiconductor devices are widely used in various fields. In order to more widely apply the organic semiconductor devices, it is necessary to understand voltage-current characteristics of an organic junction. Organic semiconductor devices having desired functions or structures can be designed by considering such voltage-current characteristics.

A representative example of conventional p-n junction organic semiconductor devices is an organic light-emitting diode (OLED). Conventional OLEDs include a hole transport layer contacting an anode and an electron transport layer contacting a cathode, wherein a light emitting layer may be disposed between the hole transport layer and the electron transport layer. When a reverse-bias voltage is applied to the conventional OLEDs, very little current flows, and when a forward-bias voltage is applied to the conventional OLEDs, no current flows until a predetermined turn-on voltage is reached and current density exponentially increases after the turn-on voltage is exceeded.

A tunneling device using Si which is an inorganic semiconductor device is applied to various fields. In general, inorganic semiconductor devices are thick and require a fabrication process at high temperature and a complicated process such as implantation for implanting dopants into silicon.

Since the organic semiconductor devices have the aforesaid advantages and are widely applicable, various researches need to be made to substitute the organic semiconductor devices for the inorganic semiconductor devices. The researches may include the introduction of a tunneling device that is applicable to an organic active device, an organic photovoltaic device, etc.

### SUMMARY OF THE INVENTION

The exemplary embodiment of the present invention is directed to an organic tunneling p-n junction device that can be easily manufactured and has improved voltage-current characteristics.

According to an exemplary embodiment of the present invention, there is provided an organic semiconductor device comprising: a p-doped organic semiconductor layer that is doped with first impurities; and an n-doped organic semiconductor layer that is doped with second impurities.

The p-doped organic semiconductor layer and the n-doped organic semiconductor layer may form a p-n junction. Each of the first impurities and the second impurities may be doped at a density of 0.1 to 80%.

The p-doped organic semiconductor layer may comprise any one selected from the group consisting of an oxadiazole compound having an amino substituent, a triphenylmethane compound having an amino substituent, a triphenyl compound having an amino substituent, a tertiary compound, a hydazone compound, a pyrazoline compound, an enamine compound, a styryl compound, a stilbene compound, and a carbazole compound.

The n-doped organic semiconductor layer may comprise any one selected from the group consisting of an anthracene compound, a phenanthracene compound, a pyrene compound, a perylene compound, a chrysene compound, a triphenylene compound, a fluoranthene compound, a periflanthene compound, a azole compound, a diazole compound, and a vinylene compound.

Highest occupied molecular orbital (HOMO) and lowest unoccupied molecular orbital (LUMO) energy levels of the n-doped organic semiconductor layer may be respectively higher than HOMO and LUMO energy levels of the p-doped organic semiconductor layer.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view of an organic tunneling p-n junction diode according to an embodiment of the present invention;

FIG. 2 is a cross-sectional view of an organic tunneling p-n junction diode according to another embodiment of the present invention;

FIG. 3 is a graph illustrating voltage-current characteristics of organic tunneling p-n junction diodes according to embodiments of the present invention;

FIG. 4A is an energy band diagram of an organic tunneling p-n junction diode under thermal equilibrium according to an embodiment of the present invention; and

FIG. 4B is an energy band diagram of the organic tunneling p-n junction diode when a reverse-bias voltage is applied to cause tunneling according to an embodiment of the present invention.

### DETAILED DESCRIPTION OF THE INVENTION

The invention is described more fully hereinafter with reference to the accompanying drawings, in which embodiments of the invention are shown. This should not be construed as limiting the claims to the embodiments shown. Rather, these embodiments are provided to convey the scope of the invention to those skilled in the art. In the drawings, the size and relative sizes of elements and regions may be exaggerated for clarity.

It will be understood that when an element or layer is referred to as being “on”, “interposed”, “disposed”, or “between” another element or layer, it can be directly on, interposed, disposed, or between the other element or layer or intervening elements or layers can be present.

The terms “first,” “second,” and the like, “primary,” “secondary,” and the like, as used herein do not denote any order, quantity, or importance, but rather are used to distinguish one element, region, component, layer, or section from another. The terms “front”, “back”, “bottom”, and/or “top” are used herein, unless otherwise noted, merely for convenience of description, and are not limited to any one position or spatial orientation.

The terms “a” and “an” do not denote a limitation of quantity, but rather denote the presence of at least one of the referenced item. The suffix “(s)” as used herein is intended to include both the singular and the plural of the term that it modifies, thereby comprising one or more of that term (e.g., the layer(s) includes one or more layers).

Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various embodiments.

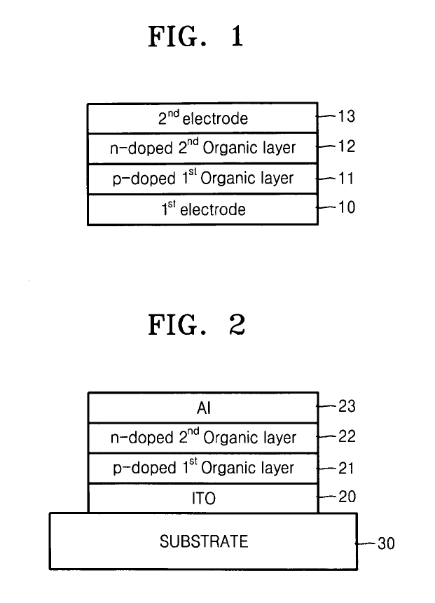

FIG. 1 is a cross-sectional view of an organic semiconductor device, e.g., an organic tunneling p-n junction diode, according to an embodiment of the present invention.

Referring to FIG. 1, the organic semiconductor device may include a p-doped first organic semiconductor layer 11 and an n-doped second organic semiconductor layer 12 which form a p-n junction. In detail, the p-doped first organic semiconductor layer 11 and the n-doped second organic semiconductor layer 12 are degenerated semiconductor layer due to doping, and thus have a potential barrier across the p-n junction. A first electrode 10 may be formed on the bottom of the p-doped first organic semiconductor layer 11 and a second electrode 13 may be formed on the top of the n-doped second organic semiconductor layer 12.

The p-n junction organic semiconductor device of FIG. 1 is turned off within an off-voltage range between a first turn-on voltage and a second turn-on voltage, and is turned on outside the off-voltage range. The off-voltage range may include 0 V. The first turn-on voltage may have a negative value. Below the first turn-on voltage, a tunneling current may exponentially decrease as a reverse-bias voltage increases whereas above the first turn-on voltage, a tunneling current may exponentially increase as a forward-bias voltage increases. Accordingly, the organic semiconductor device of FIG. 1 can achieve bidirectional tunneling effect.

P-type impurities doped into the p-doped first organic semiconductor layer 11 form charge carriers (holes) of the p-doped first organic semiconductor layer 11 and increase electric conductivity. At this time, a lowest unoccupied molecular orbital (LUMO) energy level of the p-type impurities is lower than a highest occupied molecular orbital (HOMO) energy level of the p-doped first organic semiconductor layer 11. Such p-type impurities may be selected from the group consisting of an organic material, an inorganic material, and a metal complex. The p-type impurities are doped at a density of approximately 0.1 to 80%.

The p-type impurities satisfying the above energy level conditions may include, but not limited to, at least one selected from the group consisting of F₄-TCNQ, V₂O₅, WO₃, CrO₃, WO₃, SnO₂, ZnO, MnO₂, CoO₂, and TiO₂.

The HOMO and LUMO energy levels of the p-doped first organic semiconductor layer 11 are respectively lower than HOMO and LUMO energy levels of the n-doped second organic semiconductor layer 12.

The p-doped first organic semiconductor layer 11 may include, but not limited to, at least one selected from the group consisting of an oxadiazole compound having an amino substituent, a triphenylmethane compound having an amino substituent, a triphenyl compound having an amino substituent, a tertiary compound, a hydazone compound, a pyrazoline compound, an enamine compound, a styryl compound, a stilbene compound, and a carbazole compound.

N-type impurities form charge carriers (electrons) of the n-doped second organic semiconductor layer 12 and increase electric conductivity. A HOMO energy level of the n-type impurities is higher than the LUMO energy level of the p-doped first organic semiconductor layer 11. Such n-type impurities may be selected from the group consisting of an organic material, an inorganic material, and a metal complex. The n-type impurities are doped at a density of approximately 0.1 to 80%. The HOMO and LUMO energy levels of the n-doped second organic semiconductor layer 12 are respectively higher than the HOMO and LUMO energy levels of the p-doped first organic semiconductor layer 11.

The n-type impurities satisfying the above energy level conditions may include, but not limited to, at least one selected from the group consisting of W₂(hpp)₄, Mo₂(hpp)₄, Cr₂(hpp)₄, Cs, Li, Fr, Rb, K, Cs₂CO₃, CaCO₃, K₂CO₃, Ag₂CO₃, Na₂CO₃, and Li₂CO₃.

The n-doped second organic semiconductor layer 12 may include, but not limited to, at least one selected from the group consisting of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound.

The organic semiconductor device of FIG. 1 can be applied to an organic thin film transistor (TFT), an organic photovoltaic device, an organic photo diode, and so on using a p-n junction. The bidirectional tunneling effect of the organic semiconductor device of FIG. 1 can be used for an oscillator, a bistable and monostable multivibrator, a high speed logic circuit, and a microwave low noise amplifier.

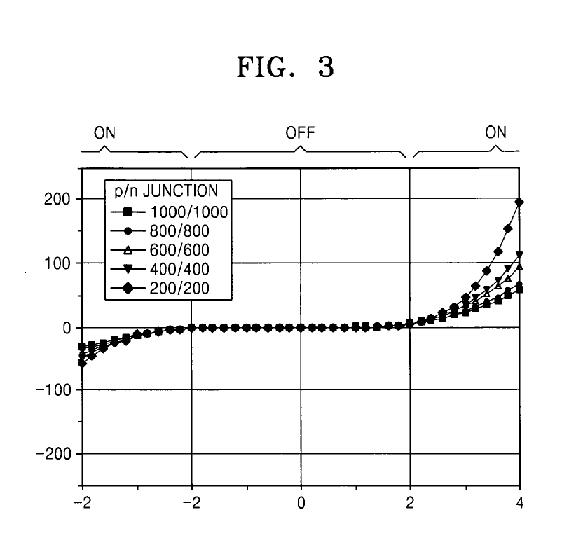

FIG. 2 is a cross-sectional view of an organic semiconductor device according to another embodiment of the present invention.

Referring to FIG. 2, a p-doped first organic semiconductor layer 21 and an n-doped second organic semiconductor layer 22 which form a p-n junction are disposed between a first electrode 20 formed of indium tin oxide (ITO) and a second electrode 23 formed of Al. The p-doped first organic semiconductor layer 21 and the n-doped second organic semiconductor layer 22 are degenerated semiconductor layers due to extrinsic doping, and thus have a potential barrier across the p-n junction. Five samples were manufactured in order to investigate characteristics of the organic semiconductor device of FIG. 2. A first electrode 20 and a second electrode 23 included in each of the first through fifth samples had thicknesses of approximately 150 nm and 200 nm, respectively. P-doped first organic semiconductor layers 21 included in the first through fifth samples had thicknesses of 200, 400, 600, 800, and 1000 Å, respectively. N-type organic semiconductor layers 22 included in the first through fifth samples and forming p-n junctions with the p-doped first organic semiconductor layers 21 had the same thicknesses as the p-doped first organic semiconductor layers 21, respectively.

The p-doped first organic semiconductor layers 21 were formed of NPB and doped with F₄-TCNQ at a density of 4%. The n-doped second organic semiconductor layers 22 were formed of Alq₃ and doped with Cs₂CO₃ at a density of 50%.

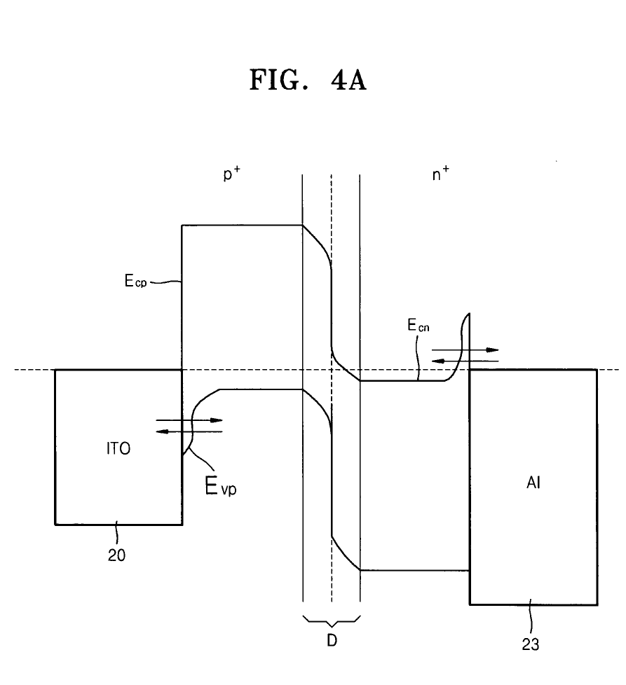

FIG. 3 is a graph illustrating voltage-current characteristics of the p-n junctions of the first through fifth samples. Referring to FIG. 3, when either a reverse-bias voltage or a forward-bias voltage is applied, all of the first through fifth samples are turned off within a predetermined voltage range of approximately −2 to +2 V, and turn-on voltages are substantially symmetric about 0 V. Current density exponentially increases outside the predetermined voltage range. A difference between the samples results from different rates of current increase caused by the different thicknesses of the organic semiconductor layers. The lower thickness of an organic semiconductor layer, the higher rate of current increase.

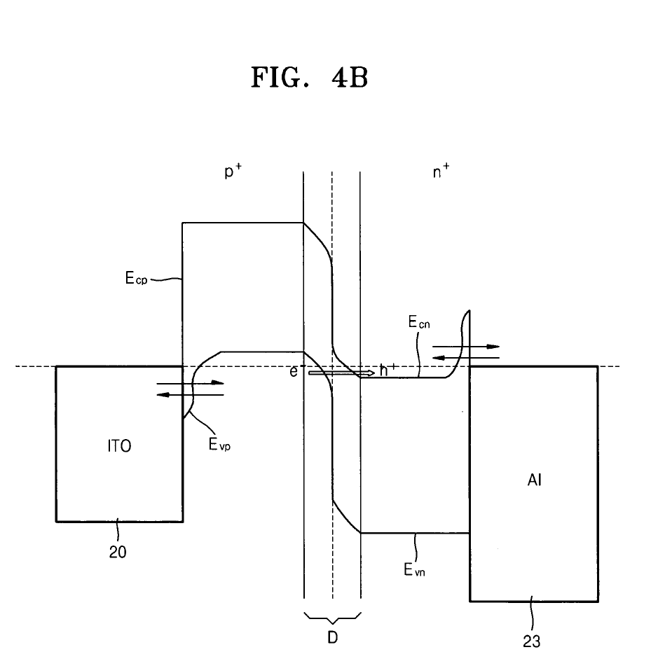

FIGS. 4A and 4B are energy band diagrams of an organic semiconductor device in different states according to embodiments of the present invention.

FIG. 4A illustrates an energy band diagram of an organic semiconductor device when a p-n junction formed between a p-doped first organic semiconductor layer p+ and an n-doped second organic semiconductor layer n+ is in a thermal equilibrium state, that is, in a steady state. Once the p-n junction is formed, holes accumulated on the p-doped first organic semiconductor layer p+ are injected into the n-doped second organic semiconductor layer n+ and electrons accumulated on the n-doped second organic semiconductor layer n+ are injected into the p-doped first organic semiconductor layer p+ to form a depletion layer D in which remaining static charges exist, an electric field is formed due to the static charges, and a Fermi level E_{f} between a conduction band bottom energy E_{cp} and a valance band top energy Eᵥₚ and between a conduction band bottom energy E_{cn} and a valence band top energy Eᵥₙ is constant at thermal equilibrium.

FIG. 4B illustrates an energy band diagram of the organic semiconductor device when a reverse-bias voltage is applied to cause tunneling. Once the reverse-bias voltage is applied, empty spaces are formed over a LUMO level of the n-doped second organic semiconductor layer n+, and electrons are occupied in a HOMO level of the p-doped first organic semiconductor layer p+. The thickness of the depletion layer D decreases due to an increase of an electric field E, such that the electrons occupied in the HOMO level of the p-doped first organic semiconductor layer p+ are tunneled to the LUMO level of the n-doped second organic semiconductor layer n+. As already described with reference to FIG. 3, current density increases as applied voltage increases. Since the thickness of the depletion layer D can be changed by controlling a doping density, a turn-on voltage can be decreased by reducing the thickness the depletion layer D.

The present invention is not limited to the exemplary embodiments, and can be applied to all organic semiconductor devices using the voltage-current characteristics.

The organic tunneling p-n junction device according to the embodiments of the present invention can be applied to active organic semiconductor devices using bidirectional current-voltage characteristics or tunneling-based fast switching characteristics as well as to organic TFTs, organic photovoltaic devices, and organic photo diodes.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic semiconductor device comprising:
a p-doped organic semiconductor layer that is doped with first impurities; and
an n-doped organic semiconductor layer that is doped with second impurities.

2. The organic semiconductor device of claim 1, wherein the p-doped organic semiconductor layer and the n-doped organic semiconductor layer form a p-n junction.

3. The organic semiconductor device of claim 1, wherein each of the first impurities and the second impurities are doped at a density of 0.1 to 80%.

4. The organic semiconductor device of claim 1, wherein the p-doped organic semiconductor layer comprises any one selected from the group consisting of an oxadiazole compound having an amino substituent, a triphenylmethane compound having an amino substituent, a triphenyl compound having an amino substituent, a tertiary compound, a hydazone compound, a pyrazoline compound, an enamine compound, a styryl compound, a stilbene compound, and a carbazole compound.

5. The organic semiconductor device of claim 1, wherein the n-doped organic semiconductor layer comprises any one selected from the group consisting of an anthracene compound, a phenanthracene compound, a pyrene compound, a perylene compound, a chrysene compound, a triphenylene compound, a fluoranthene compound, a periflanthene compound, a azole compound, a diazole compound, and a vinylene compound.

6. The organic semiconductor device of claim 3, wherein the p-doped organic semiconductor layer comprises any one selected from the group consisting of an oxadiazole compound having an amino substituent, a triphenylmethane compound having an amino substituent, a triphenyl compound having an amino substituent, a tertiary compound, a hydazone compound, a pyrazoline compound, an enamine compound, a styryl compound, a stilbene compound, and a carbazole compound.

7. The organic semiconductor device of claim 3, wherein the n-doped organic semiconductor layer comprises any one selected from the group consisting of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound.

8. The organic semiconductor device of claim 4, wherein the first impurities comprise at least one selected from the group consisting of F₄-TCNQ, V₂O₅, WO₃, CrO₃, WO₃, SnO₂, ZnO, MnO₂, CoO₂, and TiO₂.

9. The organic semiconductor device of claim 4, wherein the second impurities comprise at least one selected from the group consisting of W₂(hpp)₄, Mo₂(hpp)₄, Cr₂(hpp)₄, Cs, Li, Fr, Rb, K, Cs₂CO₃, CaCO₃, K₂CO₃, Ag₂CO₃, and Li₂CO₃.

10. The organic semiconductor device of claim 5, wherein the first impurities comprise at least one selected from the group consisting of F₄-TCNQ, V₂O₅, WO₃, CrO₃, WO₃, SnO₂, ZnO, MnO₂, CoO₂, and TiO₂.

11. The organic semiconductor device of claim 5, wherein the second impurities comprise at least one selected from the group consisting of W₂(hpp)₄, Mo₂(hpp)₄, Cr₂(hpp)₄, Cs, Li, Fr, Rb, K, Cs₂CO₃, CaCO₃, K₂CO₃, Ag₂CO₃, Na₂CO₃, and Li₂CO₃.

12. The organic semiconductor device of claim 1, wherein highest occupied molecular orbital (HOMO) and lowest unoccupied molecular orbital (LUMO) energy levels of the n-doped organic semiconductor layer are respectively higher than HOMO and LUMO energy levels of the p-doped organic semiconductor layer.

13. The organic semiconductor device of claim 2, wherein highest occupied molecular orbital (HOMO) and lowest unoccupied molecular orbital (LUMO) energy levels of the n-doped organic semiconductor layer are respectively higher than HOMO and LUMO energy levels of the p-doped organic semiconductor layer.

14. The organic semiconductor device of claim 3, wherein highest occupied molecular orbital (HOMO) and lowest unoccupied molecular orbital (LUMO) energy levels of the n-doped organic semiconductor layer are respectively higher than HOMO and LUMO energy levels of the p-doped organic semiconductor layer.
